(19) United States
(12) Patent Application Publication
(10) Pub. No.: US 2019/0289759 A1
(43) Pub. Date: Sep. 19, 2019

(54) HIGH-LOADING-LEVEL COMPOSITES FOR ELECTROMAGNETIC INTERFERENCE (EMI) APPLICATIONS

(71) Applicant: 3M INNOVATIVE PROPERTIES COMPANY, St. Paul, MN (US)

(72) Inventors: Don V. West, Minneapolis, MN (US); Craig W. Lindsay, Minneapolis, MN (US); Daniel E. Isaacson, St. Paul, MN (US); Matthew H. Frey, Cottage Grove, MN (US)

(73) Assignee: 3M INNOVATIVE PROPERTIES COMPANY, St. Paul, MN (US)

(21) Appl. No.: 16/345,184

(22) PCT Filed: Oct. 26, 2017
(86) PCT No.: PCT/US2017/058504

§ 371 Date: Apr. 25, 2019

Related U.S. Application Data
(60) Provisional application No. 62/415,022, filed on Oct. 31, 2016.

(51) Int. Cl. H05K 9/00; C08K 7/18; C08K 3/22; C08J 3/20

(52) U.S. Cl. CPC H05K 9/0083; C08K 7/18; C08K 3/22; C08J 2383/04; C08K 2003/2265; C08K 2003/2237; C08K 2003/2289; C08J 3/203

(57) ABSTRACT

Electromagnetic interference (EMI) shielding composites with high-loading-level ceramic beads and methods of making and using the same are described. The composites include high-loading-level of ceramic beads distributed inside a polymer matrix. The ceramic beads have a substantially spherical shape. The ceramic beads are formed by melting ceramic powders or particles. In some cases, the ceramic beads include ferrite beads.

### TECHNICAL FIELD

The present disclosure relates to composites or articles with high-loading-level magnetic particles for electromagnetic interference (EMI) applications in a high frequency regime, and methods of making and using the same.

### BACKGROUND

Electronic devices are more and more tightly integrated, with parts, chips, or antennas getting smaller. When device components operate at higher frequencies and in closer proximity to one another, electromagnetic interference (EMI) emissions may increase and electromagnetic compatibility (EMC) problems can be exacerbated. The decreasing size of parts poses challenges to circuit manufacture, and often results in non-ideal assemblies that lead to EMI emissions. Furthermore, larger signal losses at higher frequencies are typically addressed with increasing power of signals on circuit boards, meaning increased power of unwanted emissions. When the frequencies of operation increase to a high frequency regime, e.g., above about 18 GHz, the shielding effectiveness of enclosures may decrease significantly, yielding increased problems with emissions.

### SUMMARY

There is a desire to use more effective shielding/absorbing materials with improved electromagnetic properties in electronic devices for electromagnetic interference (EMI) applications, especially in a high frequency regime. Briefly, in one aspect, the present disclosure describes an electromagnetic interference (EMI) shielding composite including about 20 to about 60 vol % of a polymer matrix, and about 40 to about 80 vol % of ceramic beads distributed inside the polymer matrix. In some embodiments, the ceramic beads may include ferrite beads having a substantially spherical shape.

In another aspect, the present disclosure describes a method of making an electromagnetic interference (EMI) shielding composite. The method includes providing a ferrite powder precursor, processing the ferrite powder precursor to form ferrite particles, melting the ferrite particles to form ferrite beads, and compounding the ferrite beads with a polymeric matrix material to form a composite.

In another aspect, the present disclosure describes methods of making an EMI shielding composite. The method includes providing a ferrite powder precursor, mixing the ferrite powder precursor with a binder material to form a mixture, grinding the mixture, calcining the mixture at an elevated temperature to form a ferrite powder, and classifying the ferrite powder to separate ferrite particles according to a size range. The classified ferrite particles can be melted to form ferrite beads.

In another aspect, the present disclosure describes methods of making an EMI shielding composite. The method includes providing a ferrite powder precursor, mixing the ferrite powder precursor with a binder material to form a mixture, shaping the mixture into ferrite particles by filling the mixture into micromold cavities present in a substrate to form the ferrite particles, and calcining the ferrite particles at an elevated temperature. The ferrite particles can be further melted to form ferrite beads.

Various unexpected results and advantages are obtained in exemplary embodiments of the disclosure. One such advantage of exemplary embodiments of the present disclosure is that by including high-loading-level ferrite beads, the EMI shielding composites exhibit superior EMI absorber performance and mechanical properties with relatively low stiffness.

Various aspects and advantages of exemplary embodiments of the disclosure have been summarized. The above Summary is not intended to describe each illustrated embodiment or every implementation of the present certain exemplary embodiments of the present disclosure. The Drawings and the Detailed Description that follow more particularly exemplify certain preferred embodiments using the principles disclosed herein.

### BRIEF DESCRIPTION OF THE DRAWINGS

The disclosure may be more completely understood in consideration of the following detailed description of various embodiments of the disclosure in connection with the accompanying figures, in which:

FIG. 1A shows microscopic images of M-type ferrite powder.

FIG. 1B shows microscopic images of M-type ferrite beads.

FIG. 2A illustrates test results for CE-1 and E-9 showing plots for real and imaginary parts of dielectric permittivity of polymeric composites versus frequency.

FIG. 2B illustrates test results for CE-1 and E-9 showing plots for real and imaginary parts of magnetic permeability of polymeric composites versus frequency.

FIG. 3 illustrates test results for various Examples showing plots of stress versus strain for polymeric composites with various loading levels.

FIG. 4 illustrates test results for various Examples showing plots for Young's Modulus of polymeric composites versus loading levels.

FIG. 5 illustrates reflection loss as a function of frequency for CE-12 and E-9.

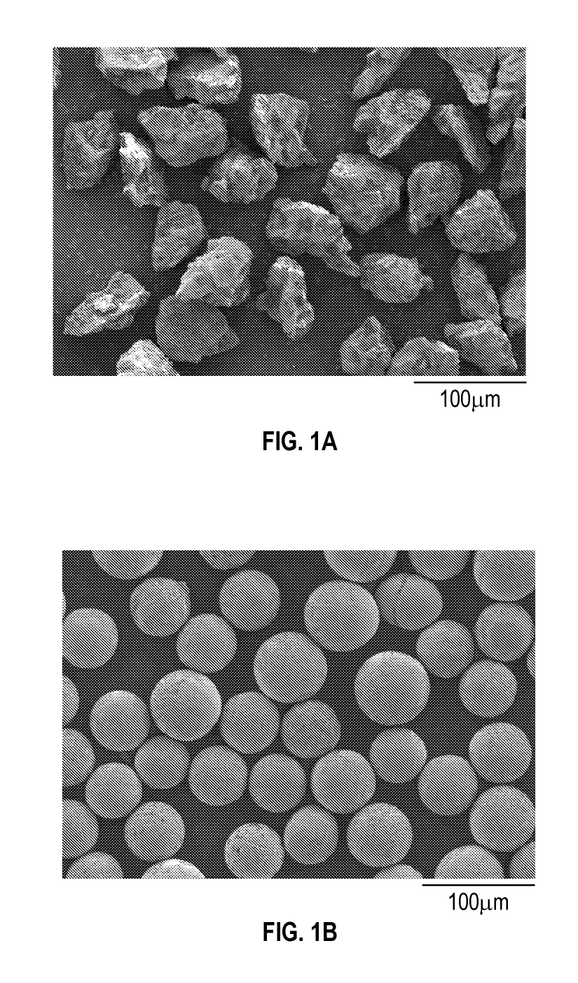

In the drawings, like reference numerals indicate like elements. While the above-identified drawing, which may not be drawn to scale, sets forth various embodiments of the present disclosure, other embodiments are also contemplated, as noted in the Detailed Description. In all cases, this disclosure describes the presently disclosed disclosure by way of representation of exemplary embodiments and not by express limitations. It should be understood that numerous other modifications and embodiments can be devised by those skilled in the art, which fall within the scope and spirit of this disclosure.

### DETAILED DESCRIPTION

For the following Glossary of defined terms, these definitions shall be applied for the entire application, unless a different definition is provided in the claims or elsewhere in the specification.

### Glossary

Certain terms are used throughout the description and the claims that, while for the most part are well known, may require some explanation. It should be understood that:

The terms “polymer” and “polymeric material” refer to both materials prepared from one monomer such as a homopolymer or to materials prepared from two or more monomers such as a copolymer, terpolymer, or the like. Likewise, the term “polymerize” refers to the process of making a polymeric material that can be a homopolymer, copolymer, terpolymer, or the like. The terms “copolymer” and “copolymeric material” refer to a polymeric material prepared from at least two monomers.

The terms “room temperature” and “ambient temperature” are used interchangeably to mean temperatures in the range of 20° C. to 25° C.

The term “spherical” is used herein to describe particles (e.g., beads) that are at least substantially spherical, and need not be perfectly spherical. Similarly, when the term “sphere” is used interchangeably with bead herein, it refers to a particle that is at least substantially spherical, and need not be perfectly spherical. The term “bead” used herein refers to a substantially spherical shape, in which distances from points on the particle surface to the particle centroid (i.e., radial distance) may vary, for example, less than about 25%, less than about 15%, less than about 10%, or less than about 5% from the average radial distance.

The terms “about” or “approximately” with reference to a numerical value or a shape means +/− five percent of the numerical value or property or characteristic, but expressly includes the exact numerical value. For example, a viscosity of “about” 1 Pa-sec refers to a viscosity from 0.95 to 1.05 Pa-sec, but also expressly includes a viscosity of exactly 1 Pa-sec. Similarly, a perimeter that is “substantially square” is intended to describe a geometric shape having four lateral edges in which each lateral edge has a length which is from 95% to 105% of the length of any other lateral edge, but which also includes a geometric shape in which each lateral edge has exactly the same length.

The term “substantially” with reference to a property or characteristic means that the property or characteristic is exhibited to a greater extent than the opposite of that property or characteristic is exhibited. For example, a substrate that is “substantially” transparent refers to a substrate that transmits more radiation (e.g. visible light) than it fails to transmit (e.g. absorbs and reflects). Thus, a substrate that transmits more than 50% of the visible light incident upon its surface is substantially transparent, but a substrate that transmits 50% or less of the visible light incident upon its surface is not substantially transparent.

As used in this specification and the appended embodiments, the singular forms “a”, “an”, and “the” include plural referents unless the content clearly dictates otherwise. Thus, for example, reference to fine fibers containing “a compound” includes a mixture of two or more compounds.

As used in this specification and the appended embodiments, the term “or” is generally employed in its sense including “and/or” unless the content clearly dictates otherwise.

As used in this specification, the recitation of numerical ranges by endpoints includes all numbers subsumed within that range (e.g. 1 to 5 includes 1, 1.5, 2, 2.75, 3, 3.8, 4, and 5).

Unless otherwise indicated, all numbers expressing quantities or ingredients, measurement of properties and so forth used in the specification and embodiments are to be understood as being modified in all instances by the term “about.” Accordingly, unless indicated to the contrary, the numerical parameters set forth in the foregoing specification and attached listing of embodiments can vary depending upon the desired properties sought to be obtained by those skilled in the art utilizing the teachings of the present disclosure. At the very least, and not as an attempt to limit the application of the doctrine of equivalents to the scope of the claimed embodiments, each numerical parameter should at least be construed in light of the number of reported significant digits and by applying ordinary rounding techniques.

The present disclosure describes electromagnetic interference (EMI) shielding composites or articles including about 20 to about 60 vol % of a polymer matrix, and about 40 to about 80 vol % of ceramic beads distributed inside the polymer matrix. Ceramic particles (e.g., ceramic beads) distributed inside a polymer matrix are also referred to herein as ceramic filler. In some embodiments, the ceramic beads may include ferrite beads having a substantially spherical shape. The EMI shielding composites or articles described herein are capable of mitigating electromagnetic interference primarily by absorption in the range of, for example, about 0.1 to about 200 GHz, about 1 to about 100 GHz, or about 10 to about 40 GHz.

The polymeric composites described herein include a polymeric matrix having desired intrinsic dielectric loss properties. Suitable polymeric matrix materials are compoundable with ceramic particles to form the polymeric composites. In some embodiments, the polymeric matrix material may include cured polymeric systems such as, for example, epoxy, silicone polycarbonate, polyester, nitrile rubber, polyurethane resin, etc. In some embodiments, the polymeric matrix material may include compoundable polymeric systems such as, for example, polypropylene, polyethylene, thermoplastic silicone, polyolefin blends (e.g., that commercially available from the Dow Chemical Company, Midland, Michigan under the trade designation Engage 8200), etc.

The polymeric composites described herein further include ceramic particles distributed inside the polymeric matrix to form the polymeric composites. In the present disclosure, a majority of the ceramic particles are in the form of beads (i.e., ceramic beads). The ceramic particles may include, for example, no less than 50 vol %, no less than 75 vol %, no less than 90 vol %, or no less than 95 vol % ceramic beads.

In some embodiments, the ceramic beads can be substantially dense spherical particles which have a low porosity level. The volume of pores inside or on the surface of the ceramic beads may be, for example, lower than 15 vol %, lower than 10 vol %, lower than 5 vol %, lower than 2 vol %, or lower than 1 vol % of the total occluded volume of the particle. In the present disclosure, the total occluded volume of a ceramic particle is the volume defined by the outermost surface of the particle. In such embodiments, the particles are described herein to include less than 15 vol % porosity, less than 10% porosity, less than 5 vol % porosity, less than 2 vol % porosity, or less than 1 vol % porosity, respectively. As used herein, the vol % of ceramic particles (e.g., ferrite beads) in a composite material refers to the vol % of the composite that is occluded by the outermost surfaces of the particles in the composite; as such, the vol % of ceramic particles (e.g., ferrite beads) may include the ceramic phase and pores that are present alongside the ceramic phase within the ceramic particles.

Suitable ceramic beads may include ferrite beads. The term “ferrites” used herein refers to ferrimagnetic ceramic compounds. In some embodiments, the ferrite beads may have a composition including M-type hexagonal AB₁₂O₁₉ ferrite, where A=Ba, Sr, or La, B═Fe, Co, Ti, Al, or Mn.

Ferrites may include, for example, a general class of oxides based on iron (II,III) oxides. Ferrites may also include spinel ferrites (e.g. nickel zinc ferrite) that are cubic ferrites used in transformer cores and high frequency filters for signal cables. Hexagonal ferrites contain a small amount of a large cation (e.g., Sr, Ba, La, Pb) leading to a hexagonal crystal structure that has spinel ferrite building blocks mixed with other motifs. Hexagonal ferrites have very strong magneto-crystalline anisotropy which results in having hard dc magnetic properties (good for permanent magnets and recording media) and also very high frequency (e.g., 300 MHz to 100 GHz) of magnetic resonance (good for high frequency magnetic absorption). Exemplary hexagonal ferrites were described in R. C. Pullar, “Hexagonal ferrites: A review of the synthesis, properties and applications of hexaferrite ceramics,” Prog. Mater. Sci., vol. 57, no. 7, pp. 1191-1334, September 2012. Applications of ferrite particles to form magnetic composites are described in, e.g., U.S. 2013/0130026 (Heikkila et al.).

The ceramic filler of interest for the present disclosure includes M-type hexagonal ferrite having a general chemical formula of AB₁₂O₁₉, where A=Ba, Sr, or La, B═Fe, (Co,Ti), Al, or Mn. Examples of AB₁₂O₁₉ include: BaM=BaFe₁₂O₁₉, SrM=SrFe₁₂O₁₉, etc. Hexagonal ferrite powders can be commercially available as, for example, a small-size powder (e.g., 0.1 to 5 microns) of single crystal platelets, a large polycrystalline powder (e.g., 0.5 to 100 microns) made up of fused hexagonal grains, or a spray-dried powder.

The present disclosure provides large (e.g., about 5 to about 500 microns) substantially dense spheres of hexagonal ferrite, which provides a facile means to create composites with very high volume fraction loadings of ferrite, for example, from about 50 to about 70 vol %, to be used as high frequency EMI absorbers.

The ceramic beads described herein can be dispersed in a polymeric matrix (e.g., a curable or compoundable matrix material) to form composites that may impart EMI absorbing properties from the ceramic beads dispersed therein. The formed composites may include, for example, about 20 to about 60 vol %, about 20 to about 50 vol %, about 20 to about 45 vol %, or about 20 to about 40 vol % of the polymer matrix. The matrix material can include, for example, epoxy, silicone, polycarbonate, polyester, nitrile rubber, polyurethane resin, etc. In some embodiments, the polymeric matrix material may include compoundable polymeric systems such as, for example, polypropylene, polyethylene, thermoplastic silicone, polyolefin blends (e.g., that commercially available from The Dow Chemical Company, Midland, Michigan, under the trade designation Engage 8200), etc. The matrix material may include a curable matrix material curable by, for example, radiation or heating, to form a radiation cured polymeric body or a thermally cured polymeric body.

The composites may further include, for example, from about 40 to about 80 vol %, from about 50 to about 80 vol %, from about 55 to about 80 vol %, from about 60 to about 80 vol %, from about 65 to about 80 vol %, from about 70 to about 80 vol %, or from about 75 to about 80 vol % of the ceramic beads to exhibit desired EMI absorbing properties. In some embodiments, the composite may include a high loading level of the ferrite beads described herein, for example, a loading level no less than about 50 vol %, no less than about 55 vol %, no less than about 60 vol %, no less than about 65 vol %, no less than about 70 vol %, or no less than about 75 vol %.

In some embodiments, the ceramic beads may have an average dimension of about 2 to about 500 microns, about 5 to about 500 microns, about 5 to about 300 microns, or about 10 to about 300 microns. In some embodiments, the ceramic beads may include a mixture of a first group of beads and a second group of beads. The first group of beads may have an average dimension of about 5 to about 30 microns, and the second group of beads may have an average dimension of about 100 to about 300 microns. In some embodiments, the ceramic beads may include more beads of the second group (larger beads) than beads of the first group (smaller beads). A weight ratio of the first and second groups of beads may be, for example, between about 1:4 and about 2:3.

In some embodiments, EMI shielding composites are provided with a mixture of a first group of ferrite filler particles and a second group of ferrite filler particles, wherein the shapes, average sizes, and particle size distributions (e.g., breadth of the particle size distributions) of the first group and the second group are independently selected in order to improve the processability and high-loading level of ferrite particles in the polymer matrix. For example, in some embodiments, the first group of ferrite particles may have an average dimension or size (e.g., diameter) of about 5 to about 30 microns, and the second group of ferrite particles may have an average dimension or size (e.g., diameter) of about 100 to about 300 microns. In some such embodiments, the second group of ferrite particles are ferrite beads, as described herein to be substantially spherical. Furthermore, the second group of ferrite particles may have a narrow size distribution, for example as described by a span (90^{th} percentile size minus 10^{th} percentile size, divided by 50^{th} percentile size) of less than 0.5, in some embodiments less than 0.4, in some embodiments, less than 0.3, in some embodiments, less than 0.2, and in yet other embodiments less than 0.1. In some embodiments, the following types of first group of ferrite particles may be combined with the aforementioned second group of ferrite particles, for example with weight ratio of the first and second groups, between about 1:4 and about 2:3. The first group of ferrite particles may be spherical or non-spherical. The first group of ferrite particles may have a broad size distribution, for example as described by a span of greater than 0.5, in some embodiments greater than 0.75, in some embodiments greater than 1, and in yet other embodiments greater than 2.

In some embodiments, the EMI shielding composites having ceramic fillers comprising first and second groups of particles having tailored size distributions (and in some embodiments shapes) as just described can include, about 40 to about 80 vol %, about 50 to about 80 vol %, about 55 to about 80 vol %, about 60 to about 80 vol %, about 70 to about 80 vol %, greater than 70 to about 80 vol %, or greater than 75 to about 80 vol % of the ceramic particles (e.g., ferrite beads); and about 20 to about 60 vol %, about 20 to about 50 vol %, about 20 to about 45 vol %, or about 20 to about 40 vol % of the polymer matrix.

In the present disclosure, by introduction of high-loading level of ferrite beads in the polymer matrix, the EMI shielding composites can exhibit superior EMI absorber performance and mechanical properties (e.g., a low stiffness). The EMI shielding composites described herein can include, about 40 to about 80 vol %, about 50 to about 80 vol %, about 55 to about 80 vol %, or about 60 to about 80 vol % of the ceramic beads; and about 20 to about 60 vol %, about 20 to about 50 vol %, about 20 to about 45 vol %, or about 20 to about 40 vol % of the polymer matrix. The composites of the present disclosure may include porosity that resides within the polymer matrix or at the interface between the polymer matrix and the ceramic filler, termed herein matrix porosity. In the expression of the amounts (e.g., vol %) components that make up the shielding composites of the present disclosure, the values that describe the amounts of polymer matrix include both the volume occupied by polymer phase and the volume of matrix porosity.

In some embodiments, the EMI shielding composites may contain other optional fillers such as, electrically conductive fillers, ferromagnetic fillers, dielectric fillers, etc. Exemplary optional fillers may include carbonyl iron powder (CIP), conductive carbon black, Sendust powders, alloys of iron, chromium and silicon, silicon carbide, etc.

The present disclosure provides various methods of making the EMI shielding composites. In some embodiments, the methods may include providing a ferrite powder precursor. Suitable ferrite powder precursor may include, for example, one or more oxides of metals A and B, where A=Ba, Sr, or La, and B═Fe, Co, Ti, Al, or Mn. The ferrite powder precursor may be hexagonal ferrite powders that are commercially available as, for example, a small-size powder (e.g., 0.1 to 5 microns) of single crystal platelets, a large polycrystalline powders (e.g., 0.5 to 100 microns) made up of fused hexagonal grains, or a spray-dried powder. The ferrite powder precursor may be mixed with a binder material to form a mixture. Suitable binder materials may include, for example, water soluble and water dispersible binders including, e.g., dextrin, starch, cellulose, hydroxyethylcellulose, hydroxypropylcellulose, carboxyethylcellulose, carboxymethylcellulose, carragenan, scleroglycan, xanthan gum, guar gum, hydroxypropylguar gum, and combinations thereof. Water can be added into the mixture to form a slurry which can be milled and dried.

In some embodiments, the mixture of the ferrite powder precursor can be ground to finer particles. In some embodiments, the mixture can be calcined to form ferrite powders by decomposing organics and carbonates. The ferrite powders may be a collection of powders with various sizes or dimensions. In some embodiments, the ferrite powder can be classified by, e.g., a sifter, to separate ferrite particles according to desired size ranges. The ferrite powder with a desired size can be further processed to form ferrite beads.

In some embodiments, the mixture of the ferrite powder precursor can be shaped into ferrite particles with desired sizes by a micro-molding process. Exemplary micro-molding processes are described in U.S. Patent Application Publication No. 2008/0041103 (Kramlich et al.), which is incorporated herein by reference. In some embodiments, the mixture can be filled into a number of micromold cavities present in a substrate. The micromold cavities are configured to have a volume proportional to the desired size of the sphere formed from the molded particles. The shaped ferrite particles can be the replica of the patterns (e.g., microstructured molds with a precise volume) on a web that include the micromold cavities. The micro-molded particles can be further processed by drying, calcining, etc.

In some embodiments, the ferrite particles can be melted to form ferrite beads having a substantially spherical shape. Suitable thermal processing methods can be used to melt the particles. One embodiment is to use a flame to treat the particles, for example by passing the particles (e.g., by gravity) through the flame. The flame can be, for example, an H₂—O₂ flame, a CH₄—O₂ flame, a plasma torch, etc. The melted particles can be air-quenched at room temperature upon exiting the flame and collected in the form of as-formed beads. The process of melting an irregularly shaped (e.g., non-spherical) ceramic particle (e.g., ferrite ceramic particle) to generate a ceramic particle having substantially spherical shape (e.g., a ceramic bead or ferrite ceramic bead) is described herein as melt-spherodization. Sphere formation in the melt-spherodization process is presumed to be driven by the surface tension of a molten ceramic droplet which forms when the ceramic particle is treated with a flame. When the surface tension is not high enough, relative to the viscosity of the molten droplet and the residence time in the thermal process (e.g., flame treatment), some non-sphericity of the resulting ceramic beads may exist, as described above.

While not wanting to be bound by theory, it is believed that melting the ferrite particles is helpful to form beads having a substantially dense spherical shape with a low porosity level. The melt-formed beads or spheres described in the present disclosure can exhibit superior properties in the application of forming highly loaded EMI shielding composites, as compared to conventional ferrite particles, spray-dried particles, and crushed and sieved particles. Some advantageous features of the melt-formed beads or spheres may include:

(1) The melt-formed beads are dense, spherical-shaped particles having less surface area than similarly sized particles that are not spherical-shaped. When compounded with a polymeric matrix material to form composites, (i) less interfacial modifier is required, and a smaller fraction of the modifier in the composite means more room for the ferrite beads, and (ii) fewer interfacial interactions may lower the viscosities for a given loading;

(2) The spherical particles (as opposed to plate-like, or jagged particles) have a lower tendency for percolation, and less inter-particle friction, thus lowering the viscosities for a given loading level; and

(3) The melt-formed particles can achieve near-full density as compared to conventional particles (e.g., spray-dried particles are more porous).

In some embodiments, the as-formed ferrite beads can be post-annealed at high temperatures, for example, between 800° C. and 1400° C. While not wanting to be bound by theory, it is believed that post-annealing can help to re-oxidize the composite of as-formed beads, reduce its electrical conductivity, and improve its electromagnetic properties. The flame used to melt the particles may be a reducing environment which may introduce oxygen deficiency and elevated levels of electrical conductivity. This may lead to elevated permittivity and dielectric loss in composites made with the beads, which may in some embodiments be desirable and in other embodiments be undesirable. In addition, the composite of as-formed beads may have nano-crystallinity (i.e., a polycrystalline grain structure wherein grains have at least one dimension less than about 100 nanometers), where the magnetic atoms may experience a large variability in magnetic environments leading to a broad dispersion of ferromagnetic resonance (FMR) frequencies. The composite of as-formed beads may exhibit a much broader and shorter magnetic loss peak.

In some embodiments, annealing the as-formed beads in an oxygen atmosphere such as, for example, air, at a first elevated temperature (e.g., about 900° C. or higher) may re-oxidize the beads and reduce the electrical conductivity. In some embodiments, annealing the as-formed beads at a second elevated temperature (e.g., about 1100° C. or higher) may coarsen crystalline grains therein enough to give a noticeable sharpening in the magnetic loss peaks. In some embodiments, full coarsening of the grains may require annealing at an even higher temperature (e.g., about 1300° C. or higher). Post-annealing may result in larger crystal grains (e.g., greater than about one micron), and sharp resonance peaks (e.g., FWHM mu(im)≤0.175 when plotted against log 10(Hz)). In some embodiments, a small amount (e.g., 0.1 to 2.0 wt. %) of bismuth oxide can be added to lower the necessary post-annealing temperature to, for example, less than 1200° C.

In some embodiments, the ferrite beads are prepared with crystalline grains in the size range of, for example, about 0.01 to about 0.1 micrometers, in some embodiments about 0.1 to about 0.5 micrometers, and in yet other embodiments about 0.5 to about 10 micrometers. In some embodiments, the ferrite beads are prepared with crystalline grains that are sized less than 20% of the diameter of the bead that they comprise, in some embodiments less than 10%, in some embodiments less than 5%, in some embodiments less than 2%.

In the present disclosure, the ferrite beads are introduced to mix with a polymeric matrix material, and optionally with other desired fillers to form polymer composites. In some embodiments, the matrix material may include a curable polymer material such as, for example, epoxy, silicone, polycarbonate, polyester, nitrile rubber, polyurethane resin, etc. In some embodiments, the polymeric matrix material may include compoundable polymeric systems such as, for example, polypropylene, polyethylene, thermoplastic silicone, polyolefin blends (e.g., that commercially available from The Dow Chemical Company, Midland, Mich., under the trade designation Engage 8200), etc.

In some embodiments, the ferrite beads can be uniformly dispersed in the polymeric matrix material to form a homogenous composite. In some embodiments, the ferrite beads can be unevenly dispersed in the matrix material. For example, a graded layer approach may be taken where the ferrite beads and/or other magnetic/dielectric fillers have a graded distribution so that the EMI shielding composite is compositionally graded to reduce impedance mismatch between the EMI shielding composite and free space. In some embodiments, other types of fillers including, for example, electrically conductive fillers, dielectric fillers, mixtures thereof, etc., can be mixed with the ferrite beads, and dispersed into the polymeric matrix material to achieve desired thermal, mechanical, electrical, magnetic, or dielectric properties.

The EMI composites described herein can exhibit superior EMI absorber performance and mechanical properties. It is known that EMI absorber performance can be improved by increasing loading level of magnetic fillers. When the loading level of convectional magnetic fillers, such as commercially available ferrite powders, in EMI composites is above a certain range, stiffness of the composite can be too high such that an EMI shielding article made from the composite may exhibit poor mechanical properties (e.g., easy for crumbling). In the present disclosure, the loading level of ferrite beads can be increased to a range (e.g., 55 vol % or higher) to obtain superior absorber performance, while keeping the corresponding stiffness sufficiently low. This opens a window for obtaining high-loading-level magnetic particles for the application of high frequency EMI absorption.

Exemplary embodiments of the present disclosure may take on various modifications and alterations without departing from the spirit and scope of the present disclosure. Accordingly, it is to be understood that the embodiments of the present disclosure are not to be limited to the following described exemplary embodiments, but is to be controlled by the limitations set forth in the claims and any equivalents thereof.

Various exemplary embodiments of the disclosure will now be described with particular reference to the Drawings. Exemplary embodiments of the present disclosure may take on various modifications and alterations without departing from the spirit and scope of the disclosure. Accordingly, it is to be understood that the embodiments of the present disclosure are not to be limited to the following described exemplary embodiments, but are to be controlled by the limitations set forth in the claims and any equivalents thereof.

### Listing of Exemplary Embodiments

Exemplary embodiments are listed below. It is to be understood that any one of embodiments 1-10 and 11-19 can be combined.

Embodiment 1 is an electromagnetic interference (EMI) shielding composite comprising:
about 20 to about 60 vol % of a polymer matrix; and
about 40 to about 80 vol % of ferrite beads distributed inside the polymer matrix,
wherein the ferrite beads have a substantially spherical shape.

Embodiment 2 is the composite of embodiment 1 comprising at least 55 vol % of the ferrite beads.

Embodiment 3 is the composite of embodiment 2, wherein the ferrite beads include M-type hexagonal AB12019 ferrite, where A=Ba, Sr, or La, B═Fe, Co, Ti, Al, or Mn.

Embodiment 4 is the composite of any one of embodiments 1-3, wherein the ferrite beads have an average dimension of about 5 to about 500 microns.

Embodiment 5 is the composite of embodiment 4, wherein the ferrite beads include a mixture of a first group of beads and a second group of beads, the first group of beads have an average dimension of about 5 to about 30 microns, and the second group of beads have an average dimension of about 100 to about 300 microns.

Embodiment 6 is the composite of embodiment 5, wherein a weight ratio of the first and second groups of beads is between about 1:4 and about 2:3.

Embodiment 7 is the composite of any one of embodiments 1-6, wherein the polymeric matrix includes one or more polymeric matrix materials of silicone, epoxy, polycarbonate, polyester, nitrile rubber, and polyurethane resin.

Embodiment 8 is the composite of any one of embodiments 1-7 further comprising about 0 to about 1.0 vol % of a surface modifier including stearic acid or silica nanoparticles.

Embodiment 9 is an electromagnetic interference (EMI) shielding article comprising the composite of any one of embodiments 1-8.

Embodiment 10 is the EMI shielding article of embodiment 9, which is capable of shielding electromagnetic radiation in the range of about 0.1 GHz to about 200 GHz primarily by absorption.

Embodiment 11 is a method of making an electromagnetic interference (EMI) shielding composite, the method comprising:
providing a ferrite powder precursor;
processing the ferrite powder precursor to form ferrite particles;
melting the ferrite particles to form ferrite beads; and
compounding the ferrite beads with a polymeric matrix material to form a composite.

Embodiment 12 is the method of embodiment 11, wherein processing the ferrite powder precursor further comprises mixing the ferrite powder precursor with a binder material to form a mixture.

Embodiment 13 is the method of embodiment 12 further comprising grinding the mixture.

Embodiment 14 is the method of any one of embodiments 11-13 further comprising classifying the ferrite particles according to a predetermined size range.

Embodiment 15 is the method of any one of embodiments 11-14, wherein processing the ferrite powder precursor further comprises forming a slurry of the ferrite powder precursor, and filling the slurry into micromold cavities to form the ferrite particles.

Embodiment 16 is the method of any one of embodiments 11-15 further comprising calcining the ferrite particles at an elevated temperature.

Embodiment 17 is the method of any one of embodiments 11-16 further comprising post-annealing the ferrite beads at a temperature between 800° C. and 1400° C.

Embodiment 18 is the method of embodiment 17, wherein the ferrite beads are post-annealed in an oxygen atmosphere.

Embodiment 19 is the method of any one of embodiments 11-18, wherein the composite comprises about 20 to about 60 vol % of the polymeric matrix material, and about 40 to about 80 vol % of the ferrite beads.

The operation of the present disclosure will be further described with regard to the following detailed examples. These examples are offered to further illustrate the various specific and preferred embodiments and techniques. It should be understood, however, that many variations and modifications may be made while remaining within the scope of the present disclosure.

### EXAMPLES

These Examples are merely for illustrative purposes and are not meant to be overly limiting on the scope of the appended claims. Notwithstanding that the numerical ranges and parameters setting forth the broad scope of the present disclosure are approximations, the numerical values set forth in the specific examples are reported as precisely as possible. Any numerical value, however, inherently contains certain errors necessarily resulting from the standard deviation found in their respective testing measurements. At the very least, and not as an attempt to limit the application of the doctrine of equivalents to the scope of the claims, each numerical parameter should at least be construed in light of the number of reported significant digits and by applying ordinary rounding techniques.

### Summary of Materials

Table 1 provides abbreviations and a source for all materials used in the Examples below:

TABLE 1

| Abbreviation | Description | Source |
|---|---|---|
| BaCO₃ | Barium carbonate (99%) | Alfa Aesar, Ward Hill, |
| | | MA |
| Fe₂O₃ | Iron (III) oxide (98%) | J T Baker, Center Valley, |
| | | PA |
| Co₃O₄ | Cobalt (II, III) oxide (99.7%) | Alfa Aesar, Ward Hill, |
| | | MA |
| TiO₂ | Titanium (IV) oxide (99.8%) | Alfa Aesar, Ward Hill, |
| | | MA |
| Epon ™ 826 resin | Low viscosity liquid epoxy used in | Momentive Waterford, |
| | coatings and composite applications | NY |
| XTJ-586 Amine | Polyetherdiamine of approximately 219 | Huntsman, The |
| Curative | g/mol molecular weight | Woodlands, TX |
| Sylgard 182 | Two-part clear silicone elastomer kit, | Dow Corning, Midland, |
| | thermal cure | MI |
| Surfactant | Surfactant available under the trade | Air Products and |
| | designation DYNOL 604 | Chemicals, Allentown, |
| | | PA |
| Cell Gum | Binder for ceramic green body particles | Hercules, Wilmington, |
| | available under the trade designation | DE |
| | AQUALON cellulose gum | |
| EW-I CIP | EW-I grade Carbonyl Iron Powder with | BASF, Ludwigshafen, |
| | an electrically insulating coating, d50 = | Germany |
| | 3.5 microns | |
| BaM Ferrite Powder | <5 μm magnetic ceramic powder | Toda Kogyo Corporation, |
| | (BaFe12O19) | Hiroshima, Japan |
| QZorb 2240-S | Magnetically loaded silicone elastomer, | Laird, London, United |
| | EMI absorbing product | Kingdom |

### Test Methods

The following test methods and procedures were employed in the evaluation of the examples that follow.

### Test Method 1 (TM-1): Characterization of Permittivity (ε) and Permeability (μ)

Electromagnetic (EM) properties of composites made by compounding the M-type ferrite powder or beads with a resin (epoxy, silicone, etc.) were characterized using a sample position independent full two-port transmission line method, as described in J. Baker-Jarvis et al., Transmission/Reflection and Short-Circuit Line Methods for Measuring Permittivity and Permeability. NIST Technical Note 1355-R (1993).

For this method, rectangular waveguides were used from 8.2-40 GHz. Owing to errors, the properties measured across bands do not usually line up perfectly. Final cross-band properties were determined by fitting a phenomenological model for permittivity and permeability to the measured data.

### Test Method 2 (TM-2): Modeling of Absorber Performance

Reflection loss of a metal-backed absorber sheet is a common performance evaluation of absorber materials. It can be calculated from the measured values of permittivity (ε) and permeability (μ) using the following equations:

$${Z}_{i n} = \sqrt{\frac{μ}{ɛ}} \cdot tanh ( \frac{j 2 π tf}{c} \sqrt{μ ɛ} )$$

$$RL ( dB ) = 20 \cdot log 10 \vert \frac{{Z}_{i n} - 1}{{Z}_{i n} + 1} \vert$$

Test Method 3 (TM-3): Estimating EM Properties with the Effective Medium Approximation

Effective dielectric and magnetic properties of hypothetical composites were estimated using Bruggemen's effective medium approximation (EMA), as described in D. A. G. Bruggemen, “Berechnung verschiedener physikalischer Konstanten von heterogenen Substanzen. I. Dielektrizitätskonstanten and Leitfähigkeiten der Mischkörper aus isotropen Substanzen,” Ann. Phys., vol. 416, pp. 636-664 (1935). Using this approximation, the properties of the constituent materials can be determined from a measurement of the composite properties according to TM-1. These constituent values can then be used to estimate the properties of a hypothetical composite of the same components mixed at a different ratio.

### Test Method 4 (TM-4): Characterization of Tensile Strength

Stress versus strain curves of composites were measured using a TA-Q800 in tensile mode. Composite samples measuring 0.75-1.00 mm thick were cut into 25 mm×5.3 mm strips. Tensile tests were done by applying a constantly increasing load of 3 N/min, up to a maximum of 18 N.

### EXAMPLES

### Preparatory Example 1

### (PE-1): Ferrite Powder

In a stainless steel beaker, 0.89 g cell-gum binder was dispersed in 39.64 g water using high shear mixing for 10 min. A final ferrite chemistry of BaFe₁₂₋₂ₓCoₓTiₓO₁₉ (x=0.55) was prepared by mixing a stoichiometric ratio of the following powders: barium carbonate (BaCO₃); iron (III) oxide (Fe₂O₃); cobalt (II,III) oxide (Co₃O₄); titanium (IV) oxide (TiO₂). The ferrite precursor powder (59.64 g) was then added to the water dispersion using high shear mixing for 10 min. The resulting slurry was ball-milled for 16-20 hours and dried to a cake. The cake was then ground into a powder, classified below 1000 μm, and calcined at 900° C. for 2 h. The calcined powder was annealed in air at 1300° C. for 1 h, after which it was further ground and classified into the desired size range through sieving.

### Preparatory Example 2

### (PE-2): Ferrite Beads

Ferrite beads were prepared in the same way as the ferrite powder with the additional step of feeding the powder downward through a flame (H₂—O₂, CH₄—O₂, or plasma torch) so that all the particles melted to form spheres. The spherical particles were air-quenched upon exiting the flame to maintain their shape. Collected ferrite beads were classified into the desired size range through sieving.

### Comparative Example 1

### (CE-1): Composite Containing Ferrite Powder

Ferrite powder was prepared according to PE-1, with a final size range of 50-300 μm. A 2-part Sylgard 182 silicone elastomer kit was prepared. The ferrite powder was weighed accordingly to achieve a 55 vol % ferrite composite mixture and was mixed by hand into the silicone matrix. The mixture was then homogenized with a speed mixer. A hot press was used to press the composite into a 1 mm thick sheet and set to cure at 250° F. under 10 tons of force for 1 h.

### Comparative Example 2

### (CE-2)

A similar procedure to CE-1 was followed, except the ferrite powder was weighed accordingly to achieve a composite comprising 10 vol % ferrite powder.

### Comparative Example 3

### (CE-3)

A similar procedure to CE-1 was followed, except the ferrite powder was weighed accordingly to achieve a composite comprising 20 vol % ferrite powder.

### Comparative Example 4

### (CE-4)

A similar procedure to CE-1 was followed, except the ferrite powder was weighed accordingly to achieve a composite comprising 40 vol % ferrite powder.

### Example 5

### (E-5): Composite Containing Ferrite Beads

Ferrite beads were prepared according to PE-2 with an average bead diameter of 50 to 200 μm. A 2-part Sylgard 182 silicone elastomer kit was prepared. The ferrite beads were weighed accordingly to achieve a 55 vol % ferrite composite mixture and were mixed by hand into the silicone matrix. The mixture was then homogenized with a speed mixer. A hot press was used to press the composite into a 1 mm thick sheet and set to cure at 250° F. under 10 tons of force for 1 h.

### Example 6

### (E-6)

A similar procedure to E-5 was followed, except the ferrite beads were weighed accordingly to achieve a composite comprising 10 vol % ferrite beads.

### Example 7

### (E-7)

A similar procedure to E-5 was followed, except the ferrite beads were weighed accordingly to achieve a composite comprising 20 vol % ferrite beads.

### Example 8

### (E-8)

A similar procedure to E-5 was followed, except the ferrite beads were weighed accordingly to achieve a composite comprising 40 vol % ferrite beads.

### Example 9

### (E-9): Composite Containing Ferrite Beads

A hypothetical composite made of 70 vol % ferrite beads in a silicone matrix was analyzed using TM-3 to calculate the theoretical permittivity and permeability. The assumed composites for the calculation are described below.

Two sets of ferrite beads were prepared according to PE-2 with the first set having an average bead diameter of about 5 to about 30 microns and the second set having an average bead diameter between 180 and 220 microns. The bimodal beads were mixed accordingly to result in a final composite containing 70 vol % ferrite beads in a silicone matrix. The silicone matrix used in the hypothetical composite E-9 was that prepared from a 2-part Sylgard 182 silicone elastomer kit.

### Comparative Example 10

### (CE-10)

QZorb 2240-S is a commercial composite absorber made with silicone and carbonyl iron powder (CIP, a commonly used EMI absorbing filler) loaded at about 40 vol %, and available in different thicknesses.

### Comparative Example 11

### (CE-11)

EW-I CIP, a commonly used commercial EMI absorber, was loaded at 40 vol % into a cured epoxy resin (Epon 826 with XTJ-568 curative, cured at 120° C.). CE-11 exhibits magnetic and dielectric properties very similar to CE-10.

### Comparative Example 3

### (CE-12)

A hypothetical composite includes 23 vol % EW-I CIP and 77 vol % epoxy resin. The measured dielectric and magnetic properties of CE-11 were used as a starting point to estimate the properties (according to TM-3) of a composite made of 23 vol % EW-I CIP and 77 vol % epoxy resin.

### Results

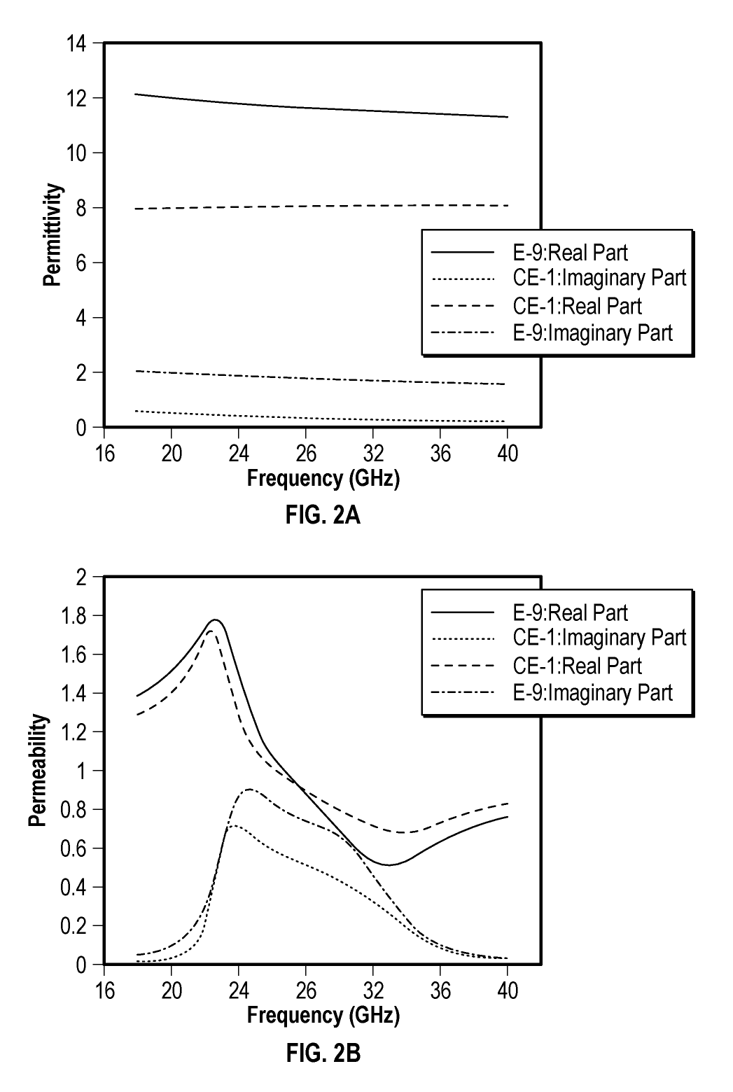

Ferrite composites CE-1 and E-9 were evaluated with respect to their electric permittivity and magnetic permeability properties and the results are shown in FIGS. 2A and 2B, respectively. Superior electric absorbing properties and magnetic properties occurred in the silicone composite containing a high loading level (e.g., 70 vol %) of fully-dense flame formed ferrite beads (e.g., E-9) when compared to that of a composite containing a comparable sintered ceramic (i.e., a silicone composite CE-1 containing 55 vol % ferrite powder). Examples CE-1 and E-9 exhibit similar mechanical properties, e.g., tensile strength, and Young's Modulus values. It is technically challenging to achieve the same high loading level (e.g., 70 vol %) for ferrite powder particles (e.g., CE-1) due to its undesired high stiffness.

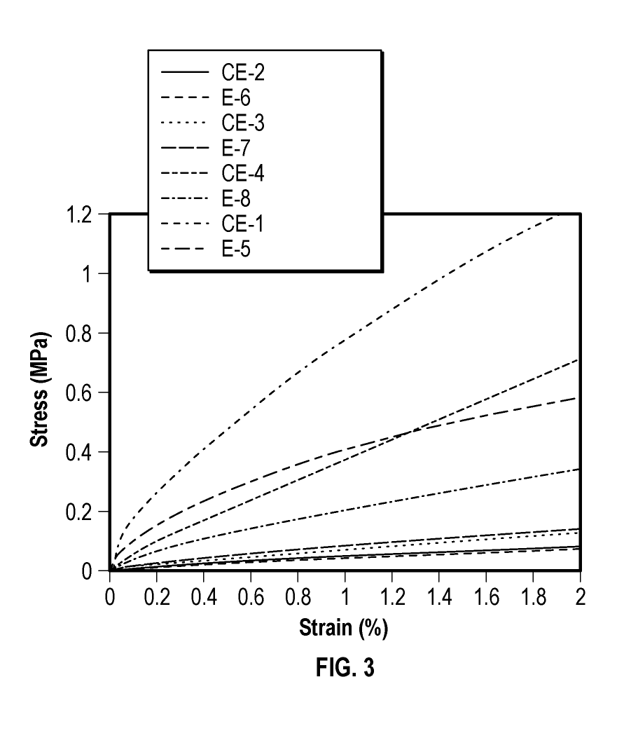

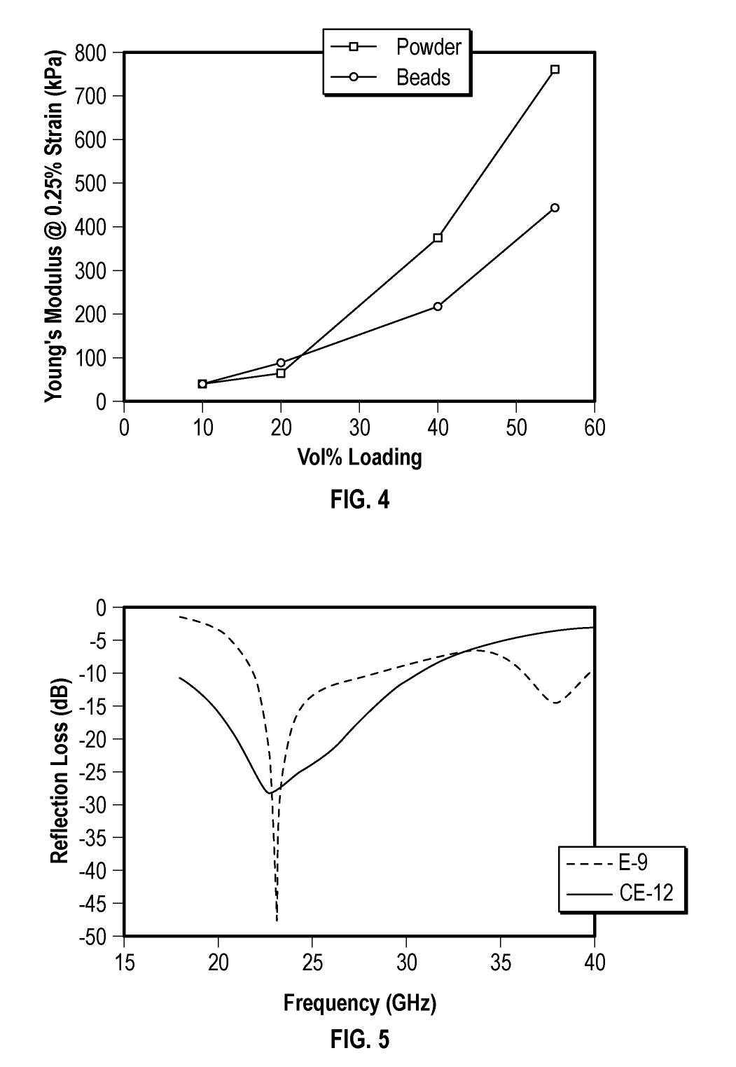

Improved composite integrity was observed at higher loading levels of ferrite beads when compared to composites made with ferrite powder. FIG. 3 illustrates test results for various Examples showing plots of strain versus stress for polymeric composites with various loading levels. As the composite filler loading level increases, the composites made with ferrite powder (CE-1 to CE-4) show increasing stiffness, which may render to the corresponding articles to crumble at certain loading level. In contrast, the composites made with ferrite beads (E-5 to E-8) have lower stiffness when the loading level is above certain value (e.g., greater than 20 vol %). This allows composites with ferrite beads to be made with a higher vol % loading without crumbling.

The EM properties of the ferrite based (E-9) and EW-1 CIP (CE-12) based composites are shown in FIG. 5. For the radar absorption model around 25 GHz, the near perfect impedance matching condition was achieved at about half of the sheet thickness for ferrite based composites (about 0.65 mm) as compared to CIP based composites (about 1.25 mm).

Reference throughout this specification to “one embodiment,” “certain embodiments,” “one or more embodiments” or “an embodiment,” whether or not including the term “exemplary” preceding the term “embodiment,” means that a particular feature, structure, material, or characteristic described in connection with the embodiment is included in at least one embodiment of the certain exemplary embodiments of the present disclosure. Thus, the appearances of the phrases such as “in one or more embodiments,” “in certain embodiments,” “in one embodiment” or “in an embodiment” in various places throughout this specification are not necessarily referring to the same embodiment of the certain exemplary embodiments of the present disclosure. Furthermore, the particular features, structures, materials, or characteristics may be combined in any suitable manner in one or more embodiments.

While the specification has described in detail certain exemplary embodiments, it will be appreciated that those skilled in the art, upon attaining an understanding of the foregoing, may readily conceive of alterations to, variations of, and equivalents to these embodiments. Accordingly, it should be understood that this disclosure is not to be unduly limited to the illustrative embodiments set forth hereinabove. In particular, as used herein, the recitation of numerical ranges by endpoints is intended to include all numbers subsumed within that range (e.g., 1 to 5 includes 1, 1.5, 2, 2.75, 3, 3.80, 4, and 5). In addition, all numbers used herein are assumed to be modified by the term “about.” Furthermore, various exemplary embodiments have been described. These and other embodiments are within the scope of the following claims.

1. An electromagnetic interference (EMI) shielding composite comprising:
about 20 to about 60 vol % of a polymer matrix; and
about 40 to about 80 vol % of ferrite beads distributed inside the polymer matrix,
wherein at least some of the ferrite beads each have a substantially spherical shape.

2. The composite of claim 1, wherein the composite comprises at least 55 vol % of the ferrite beads.

3. The composite of claim 2, wherein the ferrite beads include M-type hexagonal AB₁₂O₁₉ferrite, where A=Ba, Sr, or La, B═Fe, Co, Ti, Al, or Mn.

4. The composite of claim 1, wherein the ferrite beads have an average dimension of about 5 to about 500 microns.

5. The composite of claim 4, wherein the ferrite beads include a mixture of a first group of beads and a second group of beads, the first group of beads have an average dimension of about 5 to about 30 microns, and the second group of beads have an average dimension of about 100 to about 300 microns.

6. The composite of claim 5, wherein a weight ratio of the first and second groups of beads is between about 1:4 and about 2:3.

7. An electromagnetic interference (EMI) shielding article comprising the composite of claim 1.

8. The EMI shielding article of claim 7, which is capable of shielding electromagnetic radiation in the range of about 0.1 GHz to about 200 GHz primarily by absorption.

9. A method of making an electromagnetic interference (EMI) shielding composite, the method comprising:
providing a ferrite powder precursor;
processing the ferrite powder precursor to form ferrite particles;
melting the ferrite particles to form ferrite beads; and
compounding the ferrite beads with a polymeric matrix material to form a composite.

10. The method of claim 9, wherein processing the ferrite powder precursor further comprises mixing the ferrite powder precursor with a binder material to form a mixture.

11. The method of claim 9 further comprising classifying the ferrite particles according to a predetermined size range.

12. The method of claim 9, wherein processing the ferrite powder precursor further comprises forming a slurry of the ferrite powder precursor, and filling the slurry into micromold cavities to form the ferrite particles.

13. The method of claim 9 further comprising post-annealing the ferrite beads at a temperature between 800° C. and 1400° C.

14. The method of claim 13, wherein the ferrite beads are post-annealed in an oxygen atmosphere.

15. The method of claim 9, wherein the composite comprises about 20 to about 60 vol % of the polymeric matrix material, and about 40 to about 80 vol % of the ferrite beads.

16. The composite of claim 1, wherein the polymeric matrix includes one or more polymeric matrix materials of silicone, epoxy, polycarbonate, polyester, nitrile rubber, and polyurethane resin.
